(19) United States
(12) Patent Application Publication
(10) Pub. No.: US 2013/0224905 A1
(43) Pub. Date: Aug. 29, 2013

(54) SILVER PASTE AND USE THEREOF IN THE PRODUCTION OF SOLAR CELLS

(71) Applicant: E I Du Pont de Nemours and Company, (US)

(72) Inventors: Gareth Michael Fuge, Bristol (GB); Roberto Irizarry-Rivera, Raleigh, NC (US); Giovanna Laudisio, Bristol (GB); Michael Rose, North Yate (GB)

(73) Assignee: E I DU PONT DE NEMOURS AND COMPANY, Wilmington, DE (US)

(21) Appl. No.: 13/778,279

(22) Filed: Feb. 27, 2013

Related U.S. Application Data
(60) Provisional application No. 61/603,509, filed on Feb. 27, 2012.

(51) Int. Cl. H01L 31/0224

(52) U.S. Cl. CPC H01L 31/022425; H01L 31/0224
USPC 438/98; 252/514

(57) ABSTRACT

A silver paste comprising particulate silver, at least one glass frit, and an organic vehicle, wherein the particulate silver includes 10 to 100 wt-% of spherically-shaped silver particles, based on the total weight of the particulate silver, wherein the spherically-shaped silver particles have an average particle size in the range of 1 to 3 μm, a crystallite size in the range of 40 to 60 nm and a smooth particle surface.

### FIELD OF THE INVENTION

The invention is directed to a silver paste and its use in the production of solar cells.

TECHNICAL BACKGROUND OF THE INVENTION

A conventional solar cell structure with a p-type base has a negative electrode that is typically on the front-side or sun side of the cell and a positive electrode on the back-side. It is well known that radiation of an appropriate wavelength falling on a p-n junction of a semiconductor body serves as a source of external energy to generate electron-hole pairs in that body. The potential difference that exists at a p-n junction, causes holes and electrons to move across the junction in opposite directions, thereby giving rise to flow of an electric current that is capable of delivering power to an external circuit. Most solar cells are in the form of a silicon wafer that has been metalized, i.e., provided with metal contacts which are electrically conductive.

Most electric power-generating solar cells currently used are silicon solar cells. Electrodes in particular are made by using a method such as screen printing from metal pastes.

The production of a silicon solar cell typically starts with a p-type semiconductor substrate, in particular a p-type silicon substrate in the form of a silicon wafer on which an n-type diffusion layer of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer is formed over the entire surface of the silicon substrate. The p-n junction is formed where the concentration of the p-type dopant equals the concentration of the n-type dopant; conventional cells that have the p-n junction close to the sun side, have a junction depth between 0.05 and 0.5 μm.

After formation of this diffusion layer excess surface glass is removed from the rest of the surfaces by etching by an acid such as hydrofluoric acid.

Next, an ARC layer (antireflective coating layer) of TiOₓ, SiOₓ, TiOₓ/SiOₓ, or, in particular, SiNₓ or Si₃N₄ is formed on the n-type diffusion layer to a thickness of between 0.05 and 0.1 μm by a process, such as, for example, plasma CVD (chemical vapor deposition).

A conventional solar cell structure with a p-type base typically has a negative electrode on the front-side or sun side of the cell and a positive electrode on the back-side. The front electrode is typically applied by screen printing and drying a front-side silver paste (front electrode forming silver paste) on the ARC layer on the front-side of the cell to form a front electrode pattern, typically a grid or a web. A typical example of a grid-like pattern is a so-called H pattern which includes (i) thin parallel finger lines (collector lines) having low width and (ii) two busbars intersecting the finger lines at right angle. In addition, a back-side silver or silver/aluminum paste and an aluminum paste are screen printed (or some other application method) and successively dried on the back-side of the substrate. Normally, the back-side silver or silver/aluminum paste is screen printed onto the silicon wafer's back-side first as two parallel busbars or as rectangles (tabs) ready for soldering interconnection strings (presoldered copper ribbons). The aluminum paste is then printed in the bare areas with a slight overlap over the back-side silver or silver/aluminum. In some cases, the silver or silver/aluminum paste is printed after the aluminum paste has been printed. Firing is then typically carried out in a belt furnace for a period of 1 to 5 minutes with the wafer reaching a peak temperature in the range of 700 to 900° C. The front electrode and the back electrodes can be fired sequentially or cofired.

The aluminum paste is generally screen printed and dried on the back-side of the silicon wafer. The wafer is fired at a temperature above the melting point of aluminum to form an aluminum-silicon melt, subsequently, during the cooling phase, an epitaxially grown layer of silicon is formed that is doped with aluminum. This layer is generally called the back surface field (BSF) layer. The aluminum paste is transformed by firing from a dried state to an aluminum back electrode. The back-side silver or silver/aluminum paste is fired at the same time, becoming a silver or silver/aluminum back electrode. During firing, the boundary between the back-side aluminum and the back-side silver or silver/aluminum assumes an alloy state, and is connected electrically as well. The aluminum electrode accounts for most areas of the back electrode, owing in part to the need to form a p+ layer. A silver or silver/aluminum back electrode is formed over portions of the back-side (often as 2 to 6 mm wide busbars) as an electrode for interconnecting solar cells by means of pre-soldered copper ribbon or the like. In addition, the front-side silver paste printed as front electrode sinters and penetrates through the ARC layer during firing, and is thereby able to electrically contact the n-type layer. This type of process is generally called “firing through”.

### SUMMARY OF THE INVENTION

The invention relates to a silver paste including particulate silver, at least one glass frit, and an organic vehicle, wherein the particulate silver includes 10 to 100 wt-% (weight-%) of spherically-shaped silver particles, based on the total weight of the particulate silver, wherein the spherically-shaped silver particles have an average particle size in the range of 1 to 3 μm, a crystallite size in the range of 40 to 60 nm and a smooth particle surface.

### DETAILED DESCRIPTION OF THE INVENTION

It has been found that the silver paste of the invention can be used for the manufacture of improved front electrodes of solar cells, in particular, silicon solar cells. “Improved front electrode” means a front electrode exhibiting low contact resistance and high solder adhesion when compared with a front electrode applied and fired under the same conditions but from a silver paste containing another type of particulate silver with a smaller crystallite size.

The silver paste of the invention includes particulate silver in a proportion of, for example, 75 to 91 wt-%, or in an embodiment, 85 to 90 wt-%, based on total silver paste composition. The particulate silver itself includes 10 to 100 wt-%, or in an embodiment, 40 to 60 wt-%, based on the total weight of the particulate silver, of spherically-shaped silver particles having an average particle size in the range of 1 to 3 μm, a crystallite size in the range of 40 to 60 nm and a smooth particle surface. In other words, the particulate silver may consist of spherically-shaped silver particles having an average particle size in the range of 1 to 3 μm, a crystallite size in the range of 40 to 60 nm and a smooth particle surface, or it may include >0 to 90 wt-%, or in said embodiment, 60 to 40 wt-% of at least one silver powder other than spherically-shaped silver particles having an average particle size in the range of 1 to 3 μm, a crystallite size in the range of 40 to 60 nm and a smooth particle surface.

The spherically-shaped silver particles are distinguished by having a low aspect ratio in the range of 3 to 1:1, or, in an embodiment, 2 to 1:1. The aspect ratio is the ratio of the largest dimension to the smallest dimension and it is determined by SEM (scanning electron microscopy) and evaluating the electron microscopical images by measuring the dimensions of a statistically meaningful number of individual silver particles. The aspect ratio in the range of 3 to 1:1, or, in an embodiment, 2 to 1:1 shall express that the silver particles have a true spherical or essentially spherical shape as opposed to irregular silver particles like, for example, acicular silver particles (silver needles) or silver flakes (silver platelets). The individual silver particles when looked at under an electron microscope have a ball like or near-to-ball like shape, i.e., they may be perfectly round or almost round, elliptical or they may have an ovoid shape.

In the description and the claims the term “average particle size” is used. It shall mean the average primary particle size (mean particle diameter, d50) determined by means of laser light scattering. Laser light scattering measurements can be carried out making use of a particle size analyzer, for example, a Microtrac S3500 machine.

In the description and the claims the term “crystallite size” is used with regard to the spherically-shaped silver particles. The term shall mean the average crystallite size (mean crystallite size) in the 111 plane determined by X-ray diffraction and the Scherrer formula. The X-ray diffraction was carried out making use of a Rigaku Rint RAD-rb X-ray diffractometer. The Cu target provided a wavelength of 0.15405 nm. The Bragg plane was the (111). In the Scherrer formula

L(111)=0.94 λ/(β cos θ)

L is the crystallite size, λ is the wavelength, β is the line broadening at half the peak maximum intensity (full width−half maximum) in radians and θ is the Bragg angle.

The silver paste of the invention is a thick film conductive metal composition that can be applied by printing, in particular, screen printing.

In the description and the claims the term “smooth particle surface” is used in connection with the spherically-shaped silver particles having an average particle size in the range of 1 to 3 μm, a crystallite size in the range of 40 to 60 nm and a smooth particle surface. The skilled person will understand that term as expressing that said silver particles' surface is uniform and exhibits a smooth radius of curvature, is not or almost not porous and/or faceted and exhibits only a low roughness. Such low particle surface roughness translates into a relatively small surface area of said silver particles. Taking into account said silver particles' average particle size in the range of 1 to 3 μm it will be understood by the skilled person that said silver particles' surface area of 0.3 to 0.6 m²/g as measured by the BET method means a relatively small surface area. In other words, the fact that said silver particles' surface is smooth is mirrored by the surface area thereof of 0.3 to 0.6 m²/g as measured by the BET method.

The spherically-shaped silver particles having an average particle size in the range of 1 to 3 μm, a crystallite size in the range of 40 to 60 nm and a smooth particle surface can be produced by a reduction/precipitation process as disclosed in U.S. Pat. No. 7,648,557 B2, to which express reference is made herewith.

Said reduction/precipitation process includes the sequential steps of (a) preparing an aqueous nitric acid solution of silver salt wherein said aqueous nitric acid solution includes a silver salt, (b) preparing a reducing solution including: (i) an ascorbic acid reducing agent; (ii) one or more surface modifier(s); and (iii) a particle size modifier, and (c) mixing together the aqueous nitric acid solution of silver salt and said reducing solution to form silver powder particles in a final aqueous solution wherein said final aqueous solution has a pH of 0.5 to 2. The reduction/precipitation process further includes the steps of (d) separating said silver powder particles from said final aqueous solution; (e) providing deionized water; (f) washing the silver powder particles with said deionized water; and (g) drying said silver powder particles. Said reduction/precipitation process is a reductive process in which the spherically-shaped silver particles having an average particle size in the range of 1 to 3 μm, a crystallite size in the range of 40 to 60 nm and a smooth particle surface are precipitated by adding together an aqueous acid solution of silver salt and an aqueous acid solution including a mixture of ascorbic acid reducing agent, nitric acid, surface modifier(s), and particle size modifier(s).

The aqueous nitric acid solution of silver salt is prepared by adding a water-soluble silver salt to deionized water to form the aqueous acid silver mixture. Nitric acid is added to make the aqueous acid silver mixture acidic. Any water-soluble silver salt can be used, for example, silver nitrate, silver phosphate, and/or silver sulfate.

The reducing and particle modifier solution is prepared by first dissolving the ascorbic acid reducing agent in deionized water. Examples of suitable ascorbic acid reducing agents include L-ascorbic acid, D-ascorbic acid, their salts and related compounds such as sodium ascorbate, D-isoascorbic acid, etc.

The surface and particle size modifiers are then added to the mixture. The surface modifiers are added to control the morphology of the individual silver particles and to prevent agglomeration of the silver particles.

Examples of suitable surface modifiers for controlling the morphology of the individual silver particles include potassium sulfate, sodium sulfate, potassium phosphate, sodium phosphate, potassium carbonate, and sodium carbonate. Potassium sulfate is preferred. The amount of the surface modifier ranges from 10⁻⁵ to 10⁻² moles per gram of silver, or, in an embodiment, from 6×10⁻⁵ to 9×10⁻³ moles per gram of silver.

Examples of suitable surface modifiers for preventing agglomeration of the silver particles include gum arabic, ammonium stearate and other stearate salts, salts of polynaphthalene sulfonate formaldehyde condensate such as Daxad 19, polyethylene glycol with molecular weight ranges from 200 to 8000, and mixtures of these surfactants. The amount of the surface modifier ranges from 0.001 to greater than 0.3 grams per gram of silver, or, in an embodiment, from 0.04 to 0.20 grams per gram of silver.

Examples of suitable particle size modifiers for said reduction/precipitation process include metal colloids such as gold colloid or silver colloid. The skilled person knows how to make such colloids; a gold colloid can for example be made by reducing a gold salt with sodium citrate in aqueous medium at an elevated temperature. A silver colloid can for example be made by reducing a silver salt with a reducing agent in aqueous medium. Additional suitable particle size modifiers can be produced in situ by adding a small amount of another reducing agent such as sodium borohydride. Once the colloid is added to the reducing and particle modifier solution, the solution is typically used within 5 hours.

The process is run such that the pH of the solution after the reduction is completed (final aqueous solution) is in the range of 0.5 to 2. The pH can be measured using a conventional pH meter. The pH is adjusted by adding nitric acid to either the reducing and particle modifier solution or the aqueous nitric acid solution of silver salt prior to the formation of the silver particles.

The process can be run at concentrations of 0.15 to 1.2 moles of silver per liter of final aqueous solution, or, in an embodiment, at concentrations of 0.47 to 0.8 moles of silver per liter of final aqueous solution.

The process is typically run at temperatures from 10° C. to 35° C.

The order of preparing the aqueous nitric acid solution of silver salt and the reducing and particle modifier solution is not important. The aqueous nitric acid solution of silver salt may be prepared before, after, or contemporaneously with the reducing and particle modifier solution. Either solution can be added to the other to form the silver particles. The two solutions are mixed quickly with a minimum of agitation to avoid agglomeration of the silver particles. Alternatively, the aqueous nitric acid solution of silver salt can be slowly added to the acidic reducing and particle modifier solution over a period of, for example, one hour to form a reaction mixture that is intensely stirred during the addition.

The water is then removed from the suspension by filtration or other suitable liquid-solid separation operation and the solids are washed with deionized water until the conductivity of the wash water is 100 μS or less. The water is then removed from the silver particles and the particles are dried.

As already mentioned, the silver paste may include particulate silver other than the spherically-shaped silver particles having an average particle size in the range of 1 to 3 μm, a crystallite size in the range of 40 to 60 nm and a smooth particle surface. Such other particulate silver may have an average particle size of, for example, 0.5 to 5 μm and it may have a spherical or non-spherical shape.

The silver paste of the invention includes at least one glass frit. The glass frits serve as inorganic binder. The glass frit composition may include PbO; in an embodiment, the glass frit composition may be leadfree. The glass frit composition may include those which upon firing undergo recrystallization or phase separation and liberate a frit with a separated phase that has a lower softening point than the original softening point. The (original) softening point of the glass frit compositions may be in the range of, for example, 325 to 600° C.

The term “softening point” used herein means the glass transition temperature, determined by differential thermal analysis DTA at a heating rate of 10 K/min.

The glass frits exhibit an average particle size in the range of, for example, 0.5 to 20 μm. The glass frits content of the silver paste of the invention may be 0.5 to 5 wt-%, or, in an embodiment, 1 to 3 wt-%, based on total silver paste composition.

The glasses can be prepared by conventional glassmaking techniques, by mixing the desired components (in particular oxides like, for example, B2O3, SiO2, Al2O3, CdO, CaO, BaO, ZnO, Na2O, Li2O, PbO, ZrO2) in the desired proportions and heating the mixture to form a melt. As is well known in the art, heating may be conducted to a peak temperature of typically 800-1400° C. and for a time such that the melt becomes entirely liquid and homogeneous. The batch ingredients may, of course, be any compounds that will yield the desired oxides under the usual conditions of frit production. For example, boric oxide may be obtained from boric acid, silicon dioxide may be produced from flint, barium oxide may be produced from barium carbonate, etc. The molten glass composition is then typically poured into water to form the frit or, alternatively, it may be quenched between counter rotating stainless steel rollers to form thin glass platelets which are then milled to form a glass frit powder. The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid including the fines may be removed. Other methods of classification may be used as well.

The silver paste of the invention includes an organic vehicle. A wide variety of inert viscous materials can be used as organic vehicle. The organic vehicle may be one in which the particulate constituents (particulate silver, glass frit, other optionally present particulate constituents) are dispersible with an adequate degree of stability. The properties, in particular, the rheological properties, of the organic vehicle may be such that they lend good application properties to the silver paste, including: stable dispersion of insoluble solids, appropriate viscosity and thixotropy for application, in particular, for screen printing, appropriate wettability of the front-side of a solar cell wafer and of the paste solids, a good drying rate, and good firing properties. The organic vehicle used in the silver paste of the invention may be a nonaqueous inert liquid. The organic vehicle may be an organic solvent or an organic solvent mixture; in an embodiment, the organic vehicle may be a solution of organic polymer(s) in organic solvent(s). Use can be made of any of various organic vehicles, which may or may not include thickeners, stabilizers and/or other common additives. In an embodiment, the polymer used as constituent of the organic vehicle may be ethyl cellulose. Other examples of polymers which may be used alone or in combination include ethylhydroxyethyl cellulose, wood rosin, phenolic resins and poly(meth)acrylates of lower alcohols. Examples of suitable organic solvents include ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols. In addition, volatile organic solvents for promoting rapid hardening after application of the silver paste can be included in the organic vehicle. Various combinations of these and other solvents may be formulated to obtain the viscosity and volatility requirements desired.

The ratio of organic vehicle in the silver paste of the invention to the inorganic components (particulate silver plus glass frit plus optionally present other inorganic additives) is dependent on the method of applying the silver paste and the kind of organic vehicle used, and it can vary. Usually, the silver paste will include, for example, 75.5 to 93 wt-% of inorganic components and 7 to 24.5 wt-% of organic vehicle, based on total silver paste composition. Typically, the polymer present in the organic vehicle is in the range of, for example, 0.2 to 5 wt-%, based on total silver paste composition.

In one embodiment, the silver paste composition includes 85 to 90 wt-% particulate silver, 1 to 3 wt-% glass frit and 7 to 14 wt-% organic vehicle.

The silver paste of the invention is a viscous composition, which may be prepared by mechanically mixing the particulate silver and the glass frits with the organic vehicle. In an embodiment, the manufacturing method power mixing, a dispersion technique that is equivalent to the traditional roll milling, may be used; roll milling or other mixing technique can also be used.

The silver paste of the invention can be used as such or may be diluted, for example, by the addition of additional organic solvent(s); accordingly, the weight percentage of all the other constituents of the silver paste may be decreased.

The silver paste of the invention may be used in the production of front electrodes of solar cells, in particular silicon solar cells, or respectively in the production of the solar cells. Therefore the invention relates also to such production processes and to front electrodes and solar cells made by said production processes.

The process for the production of a front electrode may be performed by
(1) providing a solar cell wafer having an ARC layer on its front-side,
(2) printing, in particular, screen printing and drying a silver paste of the invention on the ARC layer on the front-side of the solar cell wafer to form a front electrode pattern, and
(3) firing the printed and dried silver paste.
   As a result of the process a front electrode is obtained.

In step (1) of the process a solar cell wafer, in particular a silicon wafer having an ARC layer on its front-side is provided. The silicon wafer is a conventional mono- or polycrystalline silicon wafer as is conventionally used for the production of silicon solar cells, i.e. it typically has a p-type region, an n-type region and a p-n junction. The silicon wafer has an ARC layer, for example, of TiOₓ, SiOₓ, TiOₓ/SiOₓ, or, in particular, SiNₓ or Si₃N₄ on its front-side. Such silicon wafers are well known to the skilled person; for brevity reasons reference is made to the section “TECHNICAL BACKGROUND OF THE INVENTION”. The silicon wafer may already be provided with the conventional back-side metalizations, i.e. with a back-side aluminum paste and a back-side silver or back-side silver/aluminum paste as described above in the section “TECHNICAL BACKGROUND OF THE INVENTION”. Application of the back-side silver paste may be carried out before or after the front electrode is finished. The back-side pastes may be individually fired or cofired or even be cofired with the front-side silver paste printed on the ARC layer in step (2).

In step (2) of the process a silver paste of the invention is printed, in particular screen printed on the ARC layer on the front-side of the solar cell wafer to form a front electrode pattern typically in a dry layer thickness of, for example, 3 to 30 μm and with a width of the collector lines of, for example, 30 to 150 μm.

After application of the silver paste in step (2) it is dried, for example, for a period of 1 to 100 minutes with the solar cell wafer reaching a peak temperature in the range of 100 to 300° C. Drying can be carried out making use of, for example, belt, rotary or stationary driers, in particular, IR (infrared) belt driers.

The firing of step (3) may be performed, for example, for a period of 1 to 5 minutes with the solar cell wafer reaching a peak temperature in the range of 700 to 900° C. The firing can be carried out making use of, for example, single or multi-zone belt furnaces, in particular, multi-zone IR belt furnaces. The firing may happen in an inert gas atmosphere or in the presence of oxygen, for example, in the presence of air. During firing the organic substance including non-volatile organic material and the organic portion not evaporated during the drying may be removed, i.e. burned and/or carbonized, in particular, burned and the glass frit sinters with the particulate silver. The silver paste etches the ARC layer and fires through resulting in making electrical contact with the semiconductor or silicon substrate.

What is claimed is:

1. A silver paste comprising particulate silver, at least one glass frit, and an organic vehicle, wherein the particulate silver includes 10 to 100 wt-% of spherically-shaped silver particles, based on the total weight of the particulate silver, wherein the spherically-shaped silver particles have an average particle size in the range of 1 to 3 μm, a crystallite size in the range of 40 to 60 nm and a smooth particle surface.

2. The silver paste of claim 1, wherein the particulate silver is in a proportion of 75 to 91 wt-% based on total silver paste composition.

3. The silver paste of claim 1, wherein the particulate silver is in a proportion of 85 to 90 wt-% based on total silver paste composition.

4. The silver paste of claim 1, wherein the spherically-shaped silver particles have low aspect ratio in the range of 3 to 1:1.

5. The silver paste of claim 1, wherein the glass frit contains PbO.

6. The silver paste of claim 1, wherein the glass frit is leadfree.

7. The silver paste of claim 1, wherein upon firing the glass frit undergoes recrystallization or phase separation to liberate a frit with a separated phase that has a lower softening point than the original softening point.

8. The silver paste of claim 1, wherein the glass frit has an average particle size of 0.5 to 20 μm.

9. A process for the production of a front electrode comprising the steps of:
(1) providing a solar cell wafer having an ARC layer on its front-side;
(2) preparing the silver paste of claim 1;
(3) printing, in particular, screen printing and drying the silver paste on the ARC layer on the front-side of the solar cell wafer to form a front electrode pattern; and
(4) firing the printed and dried silver paste.
